(19) United States
(12) Patent Application Publication
(10) Pub. No.: US 2021/0020999 A1
(43) Pub. Date: Jan. 21, 2021

(54) PORTABLE ENERGY COLLECTION AND STORAGE DEVICE, METHOD OF PRODUCTION, AND METHOD OF USE

(71) Applicant: KING ABDULLAH UNIVERSITY OF SCIENCE AND TECHNOLOGY, Thuwal (SA)

(72) Inventor: Muhammad Mustafa HUSSAIN, Hercules, CA (US)

(21) Appl. No.: 16/982,304

(22) PCT Filed: Mar. 4, 2019
(86) PCT No.: PCT/IB2019/051745

§ 371 Date: Sep. 18, 2020

Related U.S. Application Data
(60) Provisional application No. 62/658,010, filed on Apr. 16, 2018.

(51) Int. Cl. H01M 10/46; H01L 25/16; H02J 7/35; H01M 10/44

(52) U.S. Cl. CPC H01M 10/465; H01L 25/167; H01L 41/053; H01M 10/44; H02J 7/35

(57) ABSTRACT

A portable energy collection and storage device includes an electrically and thermally insulating substrate. At least one energy collection device is integrated into the electrically and thermally insulating substrate. At least one energy storage device is integrated into the electrically and thermally insulating substrate and is electrically coupled to the at least one energy collection device. A set of electrical contacts is integrated into the electrically and thermally insulating substrate and electrically coupled to the at least one energy storage device. The electrically and thermally insulating substrate has a thickness less than or equal to 1 mm.

### CROSS-REFERENCE TO RELATED APPLICATIONS

This application claims priority to U.S. Provisional Patent Application No. 62/658,010, filed on Apr. 16, 2018, entitled “PORTABLE ENERGY COLLECTION AND STORAGE DEVICE, METHOD OF PRODUCTION, AND METHOD OF USE,” the disclosure of which is incorporated herein by reference in its entirety.

### BACKGROUND

### Technical Field

Embodiments of the disclosed subject matter generally relate to a portable energy collection and storage device that is small enough for a person to easily carry.

### Discussion of the Background

One of the most common complaints about portable electronic devices is limited battery life. As consumers demand portable electronic devices having more features, designers and manufacturers of these devices face a trade-off between increasing processing power and increasing battery life, i.e., increasing processing power typically reduces battery life. Accordingly, more efficient processors and processing techniques have been designed to balance processing power and battery life. For example, many smartphones now include a main processor and one or more dedicated processors, which allows the smartphones to use a less powerful main processor to achieve longer battery life and a more powerful dedicated processor for specific tasks that are not performed as often as the tasks performed by the main processor.

More efficient processors and processing techniques, however, still commonly fail to provide sufficient battery life. People using portable electronics with user-replaceable batteries typically carry a spare set of batteries so that the portable electronics can be used when the installed set of batteries runs out of power. User-replaceable batteries are typically inconvenient to carry because the batteries are typically designed to conform with a standard design, e.g., A-, AA-, and AAA-type batteries. There has been a recent trend in eliminating user-replaceable batteries and using integrated batteries in order to provide more electronic devices having compact form factors. This has resulted in the rising popularity of portable battery packs that can be coupled to the portable electronics via a cable. These portable battery packs often are larger than the portable electronic device itself, and thus are inconvenient to carry. Further, these portable battery packs still require the portable battery pack to be connected to a stationary power source, e.g., a wall outlet, to recharge.

Thus, it would be desirable to provide an energy storage device in a form factor that is convenient carrying around. It would also be desirable to provide a portable energy storage device that can collect energy without being connected to a stationary power source.

### SUMMARY

According to an embodiment, there is a portable energy collection and storage device, which includes an electrically and thermally insulating substrate. At least one energy collection device is integrated into the electrically and thermally insulating substrate. At least one energy storage device is integrated into the electrically and thermally insulating substrate and is electrically coupled to the at least one energy collection device. A set of electrical contacts is integrated into the electrically and thermally insulating substrate and is electrically coupled to the at least one energy storage device. The electrically and thermally insulating substrate has a thickness that is less than or equal to 1 mm.

According to another embodiment, there is a method for forming a portable energy collection and storage device. At least one energy collection device is integrated into an electrically and thermally insulating substrate. At least one energy storage device is integrated into the electrically and thermally insulating substrate. The at least one energy collection device is electrically coupled to the at least one energy storage device. A set of electrical contacts is integrated into the electrically and thermally insulating substrate. The set of electrical contacts are electrically coupled with the at least one energy storage device. The electrically and thermally insulating substrate has a thickness of less than or equal to 1 mm.

According to a further embodiment, there is a method of using a portable energy collection and storage device. The energy collection and storage device is arranged in an environment to collect energy. The energy collection and storage device includes an electrically and thermally insulating substrate having a at least one energy collection device and at least one energy storage device integrated into the electrically and thermally insulating substrate and the at least one energy storage device is electrically coupled to the at least one energy collection device. The energy collection and storage device is coupled to an energy consuming device via a set of electrical contacts integrated into the electrically and thermally insulating substrate and electrically coupled to the at least one energy storage device. The electrically and thermally insulating substrate has a thickness that is less than or equal to 1 mm.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1A is a schematic diagram of a top view of a portable energy collection and storage device according to an embodiment;

FIG. 1B is a schematic diagram of a side view of a portable energy collection and storage device according to an embodiment;

FIGS. 1C and 1D are a schematic diagram of a portable energy collection and storage devices according to embodiments;

FIG. 2 is a flowchart of a method for forming a portable energy collection and storage device according to an embodiment;

FIG. 3 is a flowchart of a method of forming a vertical stack of electronic devices for integration into a portable energy collection and storage device according to an embodiment;

FIGS. 4A-4N are schematic diagrams of a method of forming a vertical stack of electronic devices for integration into a portable energy collection and storage device according to an embodiment;

FIG. 5 is a flowchart of a method of using a portable energy collection and storage device according to an embodiment;

FIGS. 6A-6D are schematic diagrams of energy collection by a portable energy collection and storage device according to embodiments;

FIGS. 6E-6G are schematic diagrams of using portable energy collection and storage devices to charge energy consuming devices according to embodiments.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of an energy collection and storage device and method of production and use.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

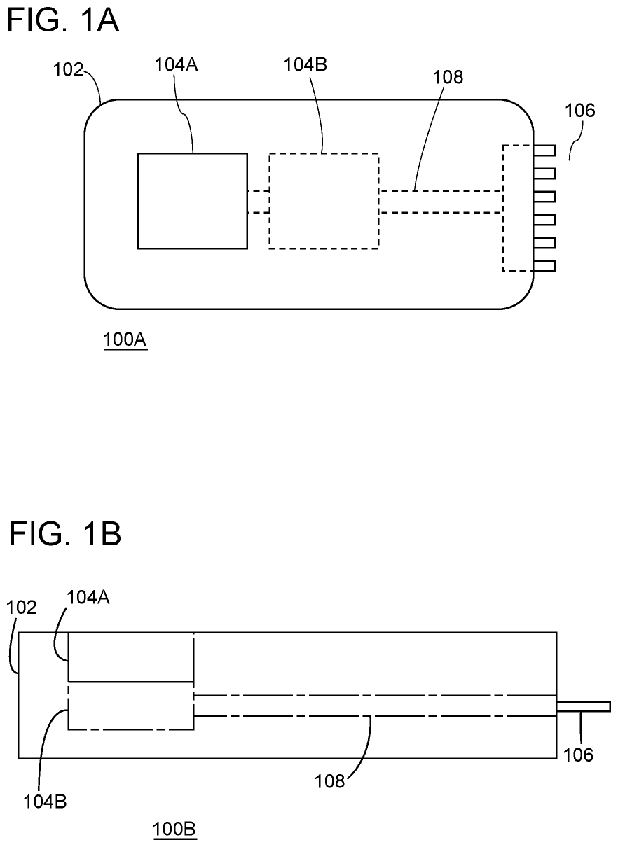

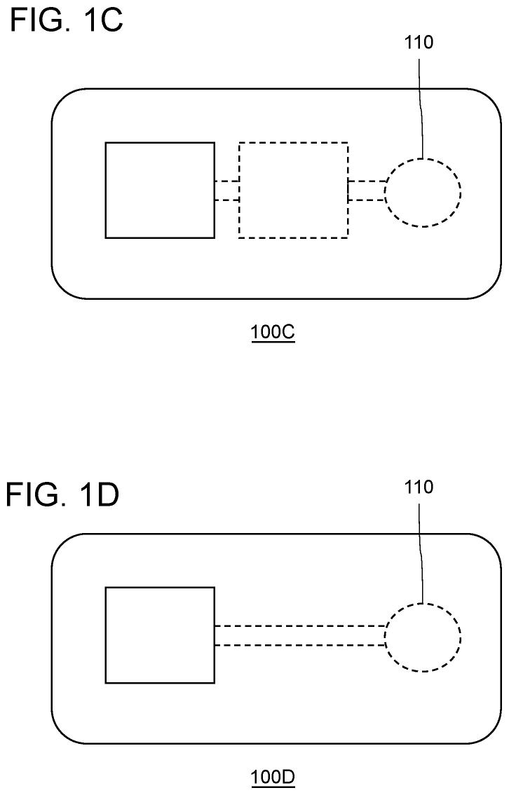

Referring now to FIGS. 1A and 1B, a portable energy collection and storage device 100A or 100B includes an electrically and thermally insulating substrate 102. At least one energy collection device 104A is integrated into the electrically and thermally insulating substrate 102. At least one energy storage device 104B is integrated into the electrically and thermally insulating substrate 102 and is electrically coupled to the at least one energy collection device 104A. A set of electrical contacts 106 is integrated into the electrically and thermally insulating substrate 102 and is electrically coupled to the at least one energy storage device 104B. The electrically and thermally insulating substrate 102 has a thickness of less than or equal to 1 mm. It should be recognized that the dashed lines in FIGS. 1A and 1B indicate components that are below the surface of the electrically and thermally insulating substrate 102; however, these components can terminate at the surface of the substrate 102, if so desired.

As will be appreciated, in the embodiment of FIG. 1A the at least one energy collection device 104A and the at least one energy storage device 104B are laterally arranged across the electrically and thermally insulating substrate 102, whereas in the embodiment of FIG. 1B the at least one energy collection device 104A and the at least one energy storage device 104B form a vertical stack that is integrated in the electrically and thermally insulating substrate 102. In other embodiments, which are not specifically illustrated, the at least one energy collection device 104A comprises at least two energy collection devices forming a vertical stack that is integrated in the electrically and thermally insulating substrate, and the at least one energy storage device 1048 and the vertical stack are laterally arranged across the electrically and thermally insulating substrate. In further embodiments, the at least one energy collection device 104A comprises at least two energy collection devices forming a vertical stack, which also includes the at least one energy storage device 1048.

In an embodiment, the electrically and thermally insulating substrate 102 can be, for example, plastic. Moreover, in an embodiment, the electrically and thermally insulating substrate 102 can have a rectangular shape. The electrically and thermally insulating substrate 102 has the general shape of a credit card, which typically conform to ISO/IEC 7810, format ID-1, which is 85.60×53.98 mm and has rounded corners with a radius of 2.88-3.48 mm and a thickness of approximately 0.76 mm. Although the ISO/IEC 7810, format ID-1 specifies a thickness of approximately 0.76 mm, a thickness that is less than or equal to 1 mm can still fit within the compartments designed for an approximately 0.76 mm thick card. This shape can be considered as rectangular even though it can have rounded corners. This form factor is particularly advantageous because it allows the portable energy collection and storage device 100A and 1008 to be carried in a compartment of a wallet, pocketbook, etc. that is already sized for credit cards. An energy storage device 1048, such as a thin-film battery, can be incorporated into a substrate conforming to ISO/IEC 7810, format ID-1 and provide approximately four hours of standby and one to one and one-half hours of talk time of power to a smartphone. It should be recognized, however, that the portable energy collection and storage device can have other form factors that also make it convenient for a person to carry, compared to the conventional bulky replacement batteries and external power chargers.

As schematically illustrated in FIGS. 1A and 1B, the electrical coupling between the at least one energy storage device 104B and the set of electrical contacts 106 can be achieved using an electrically conductive lead 108.

In the embodiments illustrated in FIGS. 1A and 1B, the set of electrical contacts 106 are arranged so that the contacts extend from one of the sides of the electrically and thermally insulating substrate 102 and are exposed. This allows the set of electrical contacts to be electrically coupled to an energy consuming device. An energy consuming device can be any type of device that consumes energy, including a smartphone, mobile phone, computer, lab-on-a-chip, a small appliance, etc.

The at least one energy collection device 104A and the at least one energy storage device 104B can be any type of device that can fit within the form factor of the portable energy collection and storage device 100A. The at least one energy collection device 104A can operate on any type of energy generation principal, such as solar, thermal, pressure, etc. For example, the at least one energy collection device 104A can be a micro-scale solar cell, piezoelectric generator using thin film or nano-structured devices, micro-scale fuel cell, microbial fuel cell, thermoelectric generator, and/or radio frequency-based energy harvesting device (e.g., an inductive charge collection device, such as, for example, those conforming to the Qi® inductive wireless charging standard). The at least one energy storage device 1048 can be, for example, a thin-film or nano-structured battery. It will be recognized that the aforementioned energy collection and energy storage devices are well-known structures that are commercially available. It should be recognized that the aforementioned energy collection and energy storage devices are examples of such devices and other types of energy collection and energy storage devices can be employed.

As discussed above, two energy collection devices can be formed into a vertical stack that includes the at least one energy storage device 1048. When a plurality of energy collection devices 104A are incorporated into the vertical stack, the energy collection devices 104A can collect energy using different energy sources. For example, the vertical stack 104 can include a solar cell arranged on one side of the stack so that it is exposed to ambient light and a thermoelectric generator arranged below the solar cell. Specifically, a first part of the thermoelectric generator can be arranged directly adjacent and below the solar cell to absorb heat generated by the solar cell, an energy storage device can be arranged directly adjacent to the first part of the thermoelectric generator, and a second part of the thermoelectric generator can be arranged directly adjacent and below the energy storage device. Thus, the first part of the thermoelectric generator can be the “hot” layer of the thermoelectric generator and the second part of the thermoelectric generator can be the “cold” layer of the thermoelectric generator such that the thermoelectric generator generates electricity based on the temperature difference between the “hot” and “cold” layers. It will be appreciated that the terms “hot” and “cold” are intended to identify that a temperature difference exists between the two layers and is not intended to specify a particular temperature or range of temperatures for these layers. Thus, this embodiment increases the power generation density by taking advantage the waste heat generated by the solar cell that is not converted into electricity by the solar cell.

Although the portable energy collection and storage devices 100A and 100B include a set of external electrical contacts 106, external contacts are not required. For example, referring now to FIGS. 10 and 1D, portable energy collection and storage devices 100C and 100D include an inductive coil (or set of coils) 110, which can transfer energy to energy consuming devices that are configured for inductive charging. In this case, the coil(s) 110 are the set of electrical contacts of the portable energy collection and storage device.

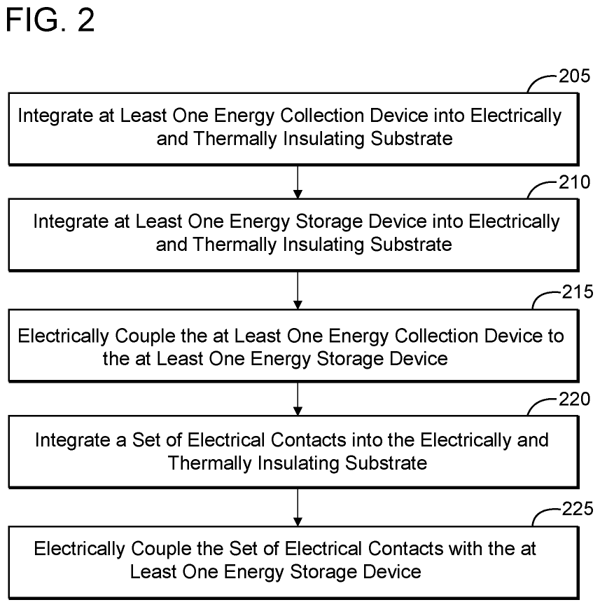

A method for forming a portable energy collection and storage device will now be described in connection with the flowchart of FIG. 2. At least one energy collection device 104A is integrated into an electrically and thermally insulating substrate 102 (step 205). At least one energy storage device 104B is integrated into the electrically and thermally insulating substrate 102 (step 210). The at least one energy collection device 104A is electrically coupled to the at least one energy storage device 104B (step 215). A set of electrical contacts are then integrated into the electrically and thermally insulating substrate 102 (step 220). In the embodiments of FIGS. 1A and 1B, the set of electrical contacts 106 are exposed contacts, whereas in the embodiments of FIGS. 10 and 1D, the set of electrical contacts 110, which are inductive charging coils, are not exposed. The electrical contacts 106 or 110 are electrically coupled to the at least one energy storage device 104B (step 225). The electrically and thermally insulating substrate 102 has a thickness that is less than or equal to 1 mm.

Arranging the at least one energy collection device 104A and the at least one energy storage device 104B in a vertical stack (as illustrated in FIGS. 1B and 1D) is particularly advantageous because of the limited space available in the form factor of the portable energy collection and storage device 100A or 100D that allows it to be conveniently carried. Forming this vertical stack as a three-dimensional integrated system, however, can be technically challenging. Specifically, most electronic devices are formed on a thick silicon wafer and stacking several of these can easily exceed the width of the electrically and thermally insulating substrate 102. For example, many electronic devices are formed on silicon substrates having thickness in the range of 300-500 μm, and thus two stacked electronic devices could easily exceed 1 mm due to the additional thickness of the electronic devices themselves. However, ISO/IEC 7810, format ID-1 defines a thickness of 0.76 mm, and thus a stack of two devices would protrude by at least 0.24 mm above the surface of the electrically and thermally insulating substrate of the portable energy collection and storage device, and thus would not be easily accommodated in structures (e.g., wallets) that are designed to accommodate payment cards and/or business cards. It will be recognized, however, that the lateral arrangement of the energy storage and/or energy collection devices allows for thicker devices without exceeding the thickness of ISO/IEC 7810, format ID-1. However, due to the lateral size constraints of the portable energy collection and storage device, a lateral arrangement can limit the size of the at least one energy storage device, whereas a vertical stack allows the at least one energy storage device to occupy a greater lateral area.

Moreover, employing thinner substrates for the electronic devices does not address all of the technological challenges for forming a three-dimensional integrated circuit. Specifically, vertically integrated electronic devices in the form of a three-dimensional integrated circuit (3D-IC) are typically produced by either forming subsequent electronic devices on top of the existing stack of electronic devices or the electronic devices can be formed separately and then stacked together. Forming subsequent electronic devices on top of the existing stack of electronic devices is problematic from a thermal perspective because forming the subsequent electronic device requires temperatures that will destroy the existing stack of electronic devices. Forming the electronic devices separately requires releasing the individual electronic devices from their original substrate, aligning the individual electronic devices with other electronic devices in the vertical stack, bonding the electronic devices of the stack, and forming vertical interconnects to electrically couple the electronic devices in the vertical stack.

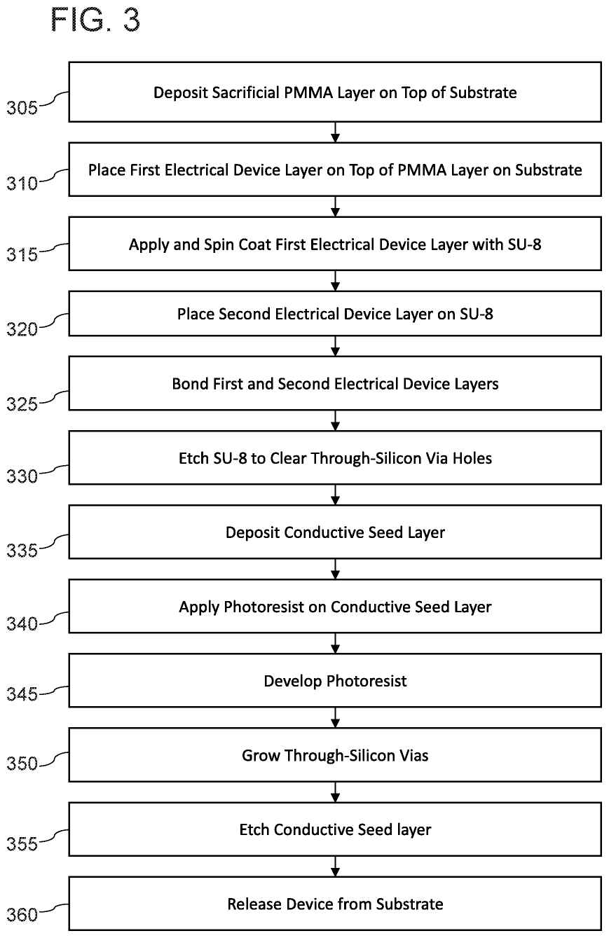

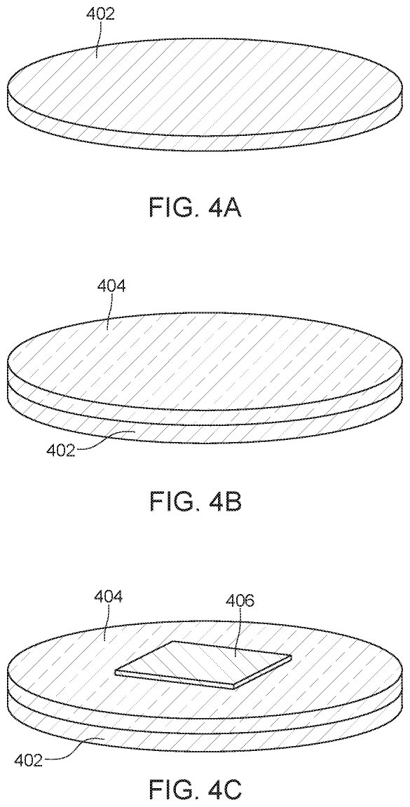

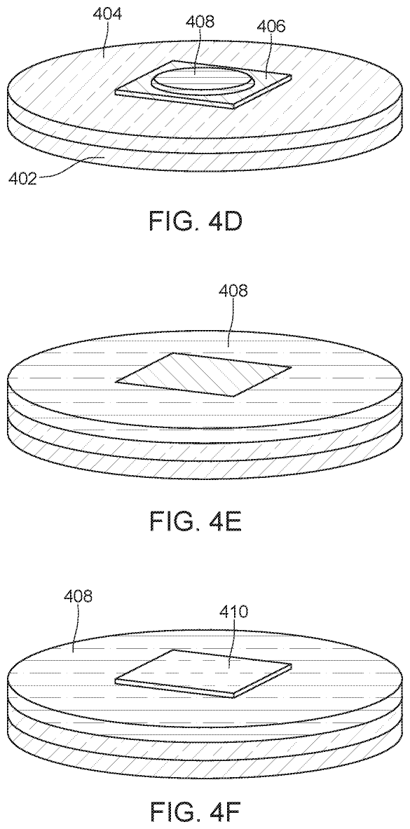

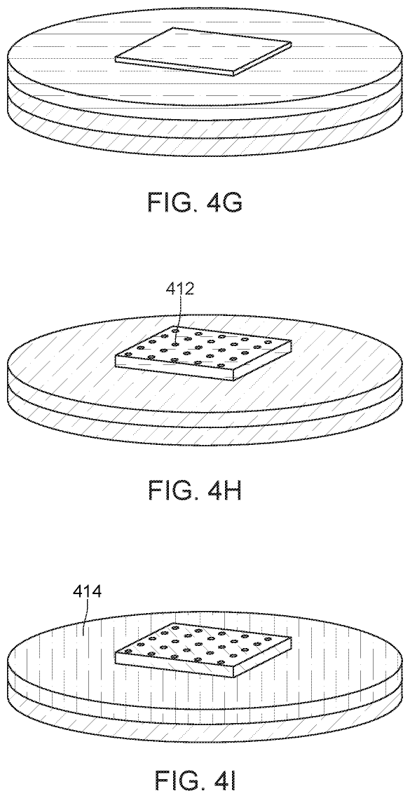

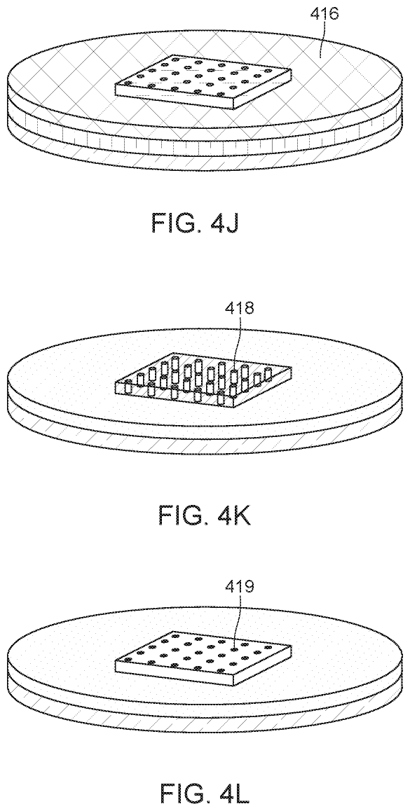

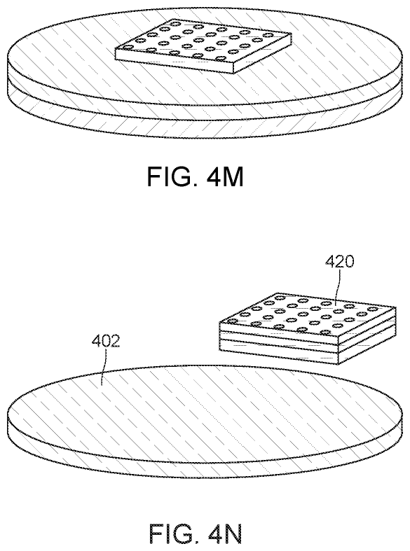

In order to address these problems, a method for low temperature three-dimensional integration of the electronic devices in the vertical stack is provided according to an embodiment, which will be discussed in more detail in connection with FIGS. 3 and 4A-4N. Initially, a sacrificial PMMA layer 404 is deposited on top of a carrier wafer 402 (step 305 and FIGS. 4A and 4B). The use of PMMA for layer 404 is particularly advantageous because it can be subsequently etched using, for example, acetone without harming the electronic devices in the vertical stack.

A first electrical device layer 406, which includes a flexible substrate carrying an electronic device, is placed on top of the PMMA layer 404 on the carrier wafer 402 (step 310 and FIG. 4C). In an embodiment, the first electrical device layer 406 includes, for example, a 30 μm thick flexible silicon substrate. SU-8 408 is applied to the first electrical device layer 406 (FIG. 4D) and then spin coated on the first electrical device layer 406 (step 315 and FIG. 4E). SU-8 is subsequently used as a bonding agent to bond the first and second electrical devices layers to each other. SU-8 is particularly advantageous because it inert to the acetone used to release the PMMA layer and also can be activated as the bonding agent at temperatures that do not affect the first and second electronic devices during the bonding process.

A second electrical device layer 410, which includes a flexible substrate carrying an electronic device, is then placed on the spin-coated SU-8 408 (step 320 and FIG. 4F). The first 406 and second 410 electrical device layers are then bonded (step 325 and FIG. 4G). The bonding can involve, for example heating the carrier wafer 402 at 95° C. for three minutes, as a pre-exposure bake, followed by exposing the SU-8 to ultraviolet radiation for six seconds, which activates the formation of an acid through a photochemical reaction with photo acid generator salt. The carrier wafer can then be heated at 95° C. for three minutes to initiate the polymerization process, during which the acid acts as a catalyst. Performing the baking and curing of the SU-8 at 95° C. results in the sacrificial PMMA layer 404 being unaffected by the bonding of the first 406 and second 410 electrical device layers. SU-8 has multiple polymerization sites per monomer with polymerization generally occurring in three dimensions, which results in the cross-linking of multiple polymer chains together to form gigantic three-dimensional molecules. These massive molecules provide mechanical and chemical stability to the cured and cross-linked SU-8 films. Generally, cross-linked SU-8 thin films are thermally stable up to 200° C. and chemically inert to most organic solvents, and thus are ideal for bonding thin flexible substrates, such as flexible silicon substrates.

The spin-coated SU-8 408 is then etched to form holes 412 for the through-silicon vias that will be subsequently formed to electrically couple the first 406 and second 410 electrical device layers (step 330 FIG. 4H). Because the SU-8 was uncured when the second electric device layer 410 is placed on the SU-8, the SU-8 may flow into holes in the substrate of the second electric device layer 410 and thus the SU-8 should be removed from the holes prior to forming the via. This can be achieved, for example, using 02 (50 sccm)/CF₄ (5 sccm) plasma reactive ion etching (RIE) at 10° C. with 150 W radio frequency power and 1500 W inductively coupled plasma (ICP power). The chamber in which the device is being formed can be maintained at a chamber pressure of, for example, 80 mTorr and the etching can take, for example, 12 minutes.

A conductive seed layer 414 (e.g., comprising 10 nm of chromium and 150 nm of gold) is then deposited on the PMMA layer 404 and the second electrical device layer 410 (step 335 and FIG. 4I). This deposition can employ, for example, an argon sputtering process (25 sccm argon, 5 mTorr, room temperature, 400 W, ESC metal sputtering system).

A photoresist 416 is spin coated on the conductive seed layer 414 (step 340 and FIG. 4J). In an embodiment, the photoresist 416 is a negative photoresist, which allows the photoresist to be easily removed from the holes 412 for the subsequent formation of the through-silicon vias. The photoresist can be, for example, AZ NLOF 2070, spun at 3000 r.p.m. for thirty seconds.

The photoresist 416 can then be developed to grow the through-silicon vias 418 (step 345 and FIG. 4K). This can involve, for example, prebaking the photoresist 416 at 100° C. for seven minutes and exposed at 200 mJ/cm². The photoresist 416 can then be post-baked at, for example, at 110° C. for sixty seconds and developed using AZ 726 MIF bath for three minutes.

Once the photoresist 416 is removed, the growth of the electrically conductive vias 419 is performed using electrochemical deposition of the conductive seed layer 414 (step 350 and FIG. 4L). This can be achieved, for example, by growing copper using a CuSO₄ bath at 25° C. with an average forward current of 0.2 A. A better conformal deposition of the conductive seed layer 414 on the sidewalls of the holes for the electrically conductive vias can be achieved by placing the device at an angle to the sputter targets. After growing the conductive seed layer 414, the photoresist 416 is removed, for example, using an acetone bath.

The conductive seed layer 414 is etched to remove excess metal (step 355 and FIG. 4M). This can be achieved using, for example, an argon plasma RIE (50 sccm, 10° C.). Finally, the device 420 is removed from the substrate 402 (step 360 and FIG. 4N).

Although the method of FIGS. 3 and 4A-4N has been described in connection with forming a device 420 having two electrical device layers 406 and 410, the device 420 can have more than two layers. In order to form the additional layers, the method is repeated (i.e., steps 320-355) for each additional layer prior to removing the device 420 from the substrate 402 (step 360). For example, a portable energy collection and storage device can be formed by bonding a first energy collection device on a first side of an energy storage device and bonding a second energy collection device on a second side of the energy storage device. Another example of forming a portable energy collection and storage device can involve bonding a thermoelectric generator to an energy storage device and bonding a solar cell on top of the thermoelectric generator so that the solar cell is arranged on top of the vertical stack.

As will be appreciated from the discussion above, the temperatures used for forming the flexible three-dimensional electronic device are around 100° C., which is significantly less than the 250-450° C. temperatures used in conventional CMOS processing. This allows the formation of electrically conductive vias through the polymer layer without affecting the mechanical or chemical stability of the polymer layer. Thus, the disclosed embodiments provide a flexible three-dimensional electronic device that exhibits good mechanical integrity during flexing, and accordingly allows for the electronic device to conform to various shaped objects.

This method of three-dimensional integration of the electronic devices in the vertical stack of electronic devices uses temperatures that allow forming the electronic devices on top of one another without destroying the existing devices in the stack, and thus avoids the alignment, bonding, and electrical coupling issues of forming the electronic devices separately and then integrating them into the vertical stack. This method also allows the formation of a stack of electronic devices having heterogeneous substrates, which provides great flexibility in the types of electronic devices integrated into a three-dimensional integrated circuit.

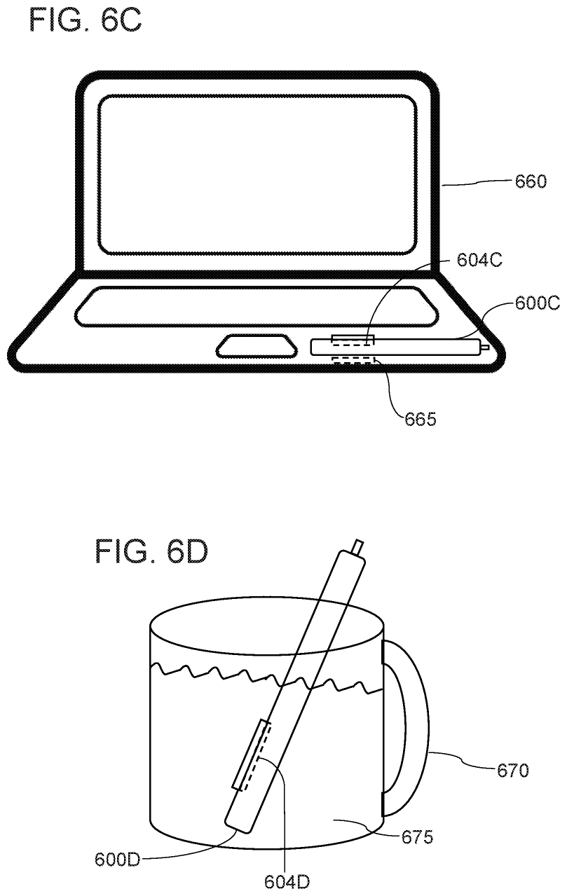

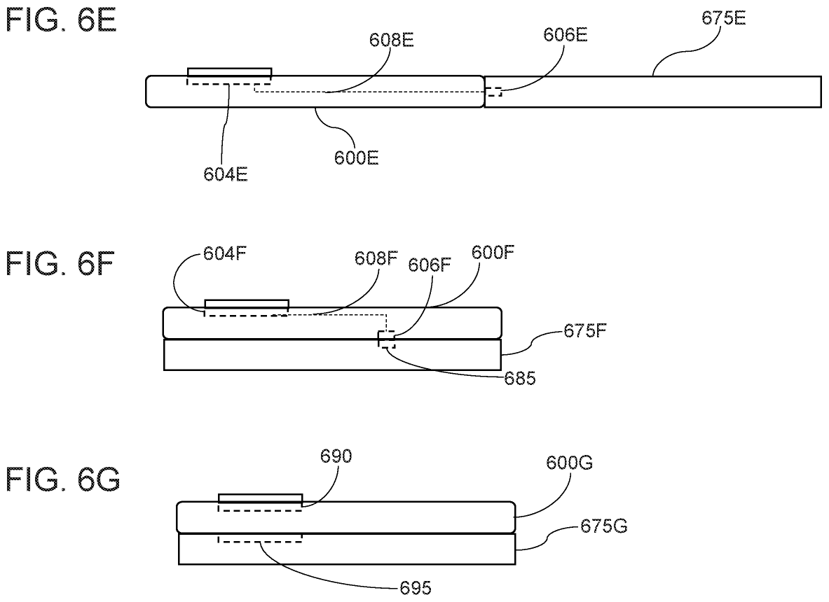

Exemplary methods of using the disclosed portable energy collection and storage device will now be described in connection with FIGS. 6A-6G. Initially, the disclosed energy collection and storage device is arranged in an environment to collect energy (step 505). For example, as illustrated in FIG. 6A, the energy collection and storage device 600A includes a solar cell as the at least one energy collection device 604A, and accordingly, the solar cell 604A is exposed on a surface of the energy collection and storage device 600A and arranged so that it can be exposed to solar energy 650.

In the example illustrated in FIG. 6B, the energy collection and storage device 600B includes a piezoelectric generator (e.g., configured as a thin film or nano-structured device) as the at least one energy collection device 604B. Accordingly, an object 655, such as a book or any other object, is placed on top of the piezoelectric generator 604B, which generates energy based on the pressure exerted on the piezoelectric generator 604B due to the gravity acting on the object 655. Although FIG. 6B designates the piezoelectric generator 604B as being exposed and the top-most electronic device of the vertical stack, the piezoelectric generator 604B can be located anywhere within the vertical stack so long as it can be subjected to external pressure.

In the example illustrated in FIG. 6C, the energy collection and storage device 600C includes a radio frequency (RF) energy harvesting device as the at least one energy collection device 604C. Accordingly, another device, such as computer 660 in the illustrated embodiment, includes a corresponding RF energy broadcasting device 665, which generates and propagate RF energy that can be converted by RF energy harvesting device 604C from RF energy into a form suitable for storage in the energy storage device. In another embodiment, the energy collection and storage device 600C includes a thermoelectric generator as the at least one energy collection device 604C, in which case the computer 660 need not, but can, include the RF energy broadcasting device 665. Accordingly, the energy collection and storage device 600C can be placed on a portion of computer 660 that generates heat so that the thermoelectric generator 604C is exposed to the heat and converts the heat into a form suitable for storage in the associated energy storage device. Although FIG. 6C illustrates the RF energy collection device or thermoelectric generator 604A3 as being underneath another device, the device/generator 604C can be located in any position within the vertical stack of devices so long as it can receive RF energy (in the case of an RF energy harvesting device) or be exposed to external heat (in the case of a thermoelectric generator).

In the example illustrated in FIG. 6D, the energy collection and storage device 600D includes a thermoelectric generator as the at least one energy collection device 604D. Accordingly, the energy collection and storage device 600D can be placed in a cup 670 that includes a liquid 675, such as water. The thermoelectric generator 604D converts the heat from the liquid 675 into a form suitable for storage in the associated energy storage device. Although FIG. 6D illustrates the thermoelectric generator 604D as being underneath another device, the thermoelectric generator 604D can be located in any position within the vertical stack of devices so long as it can be exposed to external heat.

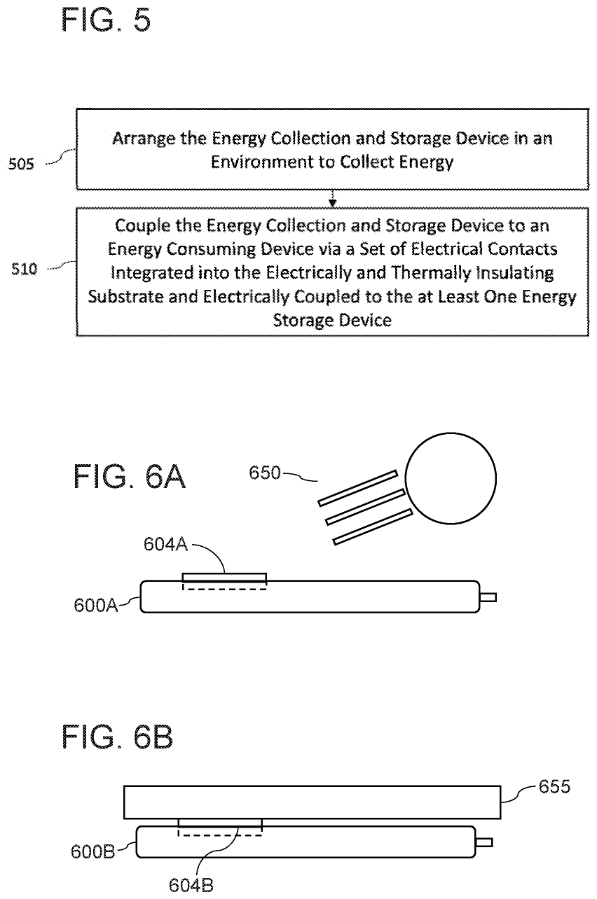

Returning to FIG. 5, the method of use also involves coupling the energy collection and storage device to an energy consuming device via a set of electrical contacts that are integrated into the electrically and thermally insulating substrate and electrically coupled to the at least one energy storage device (step 510). For example, FIG. 6E illustrates a physical, direct coupling. Specifically, an energy storage device 604E is coupled to an energy consuming device 675E via conductive lead 608E and the set of electrical contacts 606E located in a lateral end of the energy collection and storage device 600E. FIG. 6F illustrates another example of a physical, direct coupling between the energy collection and storage device 600F and energy consuming device 675F. Specifically, the energy collection and storage device 600F includes a set of electrical contacts 606F arranged on lateral side of the energy collection and storage device 600F so that the set of electrical contacts 606F can physically and electrically contact a corresponding set of electrical contacts 685 arranged on a lateral side of energy consuming device 675F.

The energy collection and storage device can also charge an energy consuming device via an indirect contact, an example of which is illustrated in FIG. 6G. Specifically, the energy collection and storage device 600G includes a coil 690 (e.g., an inductive or capacitive coil) that can wirelessly transfer power to a corresponding coil 695 of an energy consuming device 675G.

In one embodiment, the energy consuming device 675F in FIG. 6F and/or 675G in FIG. 6G can include a compartment integrated into its housing to accept the energy collection and storage device to simply aligning the contacts (in the FIG. 6F embodiment) or the coils (in the FIG. 6G embodiment).

It should be recognized that FIGS. 6E-6G are not scaled drawings, and accordingly the energy consuming devices illustrated in these figures can be bigger than, smaller than, or of equal size with the energy collection and storage device.

For ease of explanation, embodiments have been described in connection with the use of a single energy collection and storage device. It should be recognized, however, that due to its size, a person can easily carry and use multiple energy collection and storage devices. For example, a wallet or pocketbook having compartments sized for credit cards, identification cards, driver's licenses, etc., can be used to carry multiple energy collection and storage devices.

The disclosed embodiments provide a system and method for an energy collection and storage device. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A portable energy collection and storage device, comprising:
an electrically and thermally insulating substrate;
at least one energy collection device integrated into the electrically and thermally insulating substrate;
at least one energy storage device integrated into the electrically and thermally insulating substrate and electrically coupled to the at least one energy collection device; and
a set of electrical contacts integrated into the electrically and thermally insulating substrate and electrically coupled to the at least one energy storage device,
wherein the electrically and thermally insulating substrate has a thickness less than or equal to 1 mm.

2. The portable energy collection and storage device of claim 1, wherein the at least one energy collection device and the at least one energy storage device are laterally arranged across the electrically and thermally insulating substrate.

3. The portable energy collection and storage device of claim 1, wherein the at least one energy collection device and the at least one energy storage device form a vertical stack that is integrated in the electrically and thermally insulating substrate.

4. The portable energy collection and storage device of claim 1, wherein the at least one energy collection device comprises at least two energy collection devices forming a vertical stack that is integrated in the electrically and thermally insulating substrate, and the at least one energy storage device and the vertical stack are laterally arranged across the electrically and thermally insulating substrate.

5. The portable energy collection and storage device of claim 1, wherein the at least one energy collection device is a solar cell, piezoelectric energy generator, fuel cell, microbial fuel cell, thermoelectric generator, or radio frequency energy harvesting device.

6. The portable energy collection and storage device of claim 1, wherein the at least one energy collection device comprises:
a plurality of energy collection devices, each electrically coupled to the at least one energy storage device, wherein at least two of the plurality of energy collection devices are configured to collect energy using different energy sources.

7. The portable energy collection and storage device of claim 6, wherein a first and second energy collection devices of the at least two of the plurality of energy collection devices are arranged in a vertical stack, the first energy collection device is arranged on a first side of the at least one energy storage device in the vertical stack and the second energy collection device is arranged on a second side of the at least one energy storage device in the vertical stack.

8. The portable energy collection and storage device of claim 6, wherein the plurality of energy collection devices are arranged in a vertical stack and comprise:
a solar cell arranged in the vertical stack so that it is exposed to light;
a thermoelectric generator arranged below the solar cell in the vertical stack.

9. The portable energy collection and storage device of claim 8, wherein the thermoelectric generator comprises a warm layer and a cold layer, the warm layer is arranged adjacent to the solar cell, and the at least one energy storage device is arranged in the vertical stack between the warm and cold layers.

10. The portable energy collection and storage device of claim 7, wherein the at least one energy collection device and the at least one energy storage device form a vertical stack that is integrated in the electrically and thermally insulating substrate, the device further comprising:
through substrate vias passing through a substrate of one of the at least one energy collection device to the at least one energy storage device so as to electrically connect the at least one energy collection device and the at least one energy storage device to each other.

11. A method for forming a portable energy collection and storage device, the method comprising:
integrating at least one energy collection device into an electrically and thermally insulating substrate;
integrating at least one energy storage device into the electrically and thermally insulating substrate;
electrically coupling the at least one energy collection device to the at least one energy storage device;
integrating a set of electrical contacts into the electrically and thermally insulating substrate; and
electrically coupling the set of electrical contacts with the at least one energy storage device,
wherein the electrically and thermally insulating substrate has a thickness less than or equal to 1 mm.

12. The method of claim 11, wherein the at least one energy collection device and the at least one energy storage device form a vertical stack that is integrated into the electrically and thermally insulating substrate, the method further comprising:
forming the vertical stack of electronic devices by
forming the at least one energy collection device;
forming the at least one energy storage device; and
bonding the at least one energy collection device and the at least one energy storage device to form the vertical stack.

13. The method of claim 12, further comprising:
forming at least one via through a substrate of one of the at least one energy collection device and the at least one energy storage device to form the electrical coupling between the at least one energy collection device and the at least one energy storage device.

14. The method of claim 12, wherein the bonding is performed using an epoxy-based resin with a single monomer containing eight epoxide groups.

15. The method of claim 12, wherein the at least one energy collection device includes first and second energy collection devices and the forming of the vertical stack of electronic devices further comprises:
bonding the first energy collection device on a first side of the at least one energy storage device; and
bonding the second energy collection device on a second side of the at least one energy storage device.

16. The method of claim 12, wherein the at least one energy collection device includes a solar cell and a thermoelectric generator, and the forming of the vertical stack of electronic devices further comprises:
bonding the thermoelectric generator to the at least one energy storage device; and
bonding the solar cell to the thermoelectric generator so that the solar cell is arranged at a top of the vertical stack of electronic devices.

17. A method of using a portable energy collection and storage device, the method comprising:
arranging the energy collection and storage device in an environment to collect energy, wherein the energy collection and storage device includes an electrically and thermally insulating substrate having at least one energy collection device and at least one energy storage device integrated into the electrically and thermally insulating substrate and the at least one energy storage device is electrically coupled to the at least one energy collection device; and
coupling the energy collection and storage device to an energy consuming device via a set of electrical contacts integrated into the electrically and thermally insulating substrate and electrically coupled to the at least one energy storage device,
wherein the electrically and thermally insulating substrate has a thickness that is less than or equal to 1 mm.

18. The method of claim 17, wherein the arranging of the energy collection and storage device in the environment to collect energy comprises:
arranging the energy collection and storage device so that it is exposed to light.

19. The method of claim 17, wherein the arranging of the energy collection and storage device in the environment to collect energy comprises:
arranging the energy collection and storage device on an electronic device so that the energy collection and storage device is exposed to heat generated by the electronic device.

20. The method of claim 17, wherein the at least one energy collection device is a piezoelectric device configured to generate energy based on compression, and the arranging of the energy collection and storage device in the environment to collect energy comprises:
arranging the energy collection and storage device underneath an object so that piezoelectric device is compressed.
